(19) United States
(12) Patent Application Publication
(10) Pub. No.: US 2026/0075721 A1
(43) Pub. Date: Mar. 12, 2026

(54) ELECTRIC HEATING ELEMENT PRODUCTION METHOD

(71) Applicant: OERLIKON METCO AG, WOHLEN, WOHLEN (CH)

(72) Inventor: Alexander Rudolf Gebhard BARTH, KONSTANZ (DE)

(21) Appl. No.: 18/997,008

(22) PCT Filed: Jul. 3, 2023
(86) PCT No.: PCT/EP2023/000043

§ 371 Date: Jan. 18, 2025

Related U.S. Application Data
(60) Provisional application No. 63/390,399, filed on Jul. 19, 2022.

(51) Int. Cl. H05K 3/14; H05B 3/14; H05B 3/26

(52) U.S. Cl. CPC H05K 3/14; H05B 3/141; H05B 3/265; H05B 2203/003; H05B 2203/013; H05B 2203/017

(57) ABSTRACT

Post-processing of electrically conductive tracks formed from a metal coating deposited by thermal spraying on an insulating surface. In order to compensate deviations in the resulting electrical resistance caused by variations in coating thickness or coating structure, the track width is adjusted after producing the track. The adjustment of the track width can be done on an adjustment section provided along a length of the conductive track or on the full track length.

### BACKGROUND OF THE INVENTION

### 1. Field of the Invention

An electric circuit can be formed by applying an electrically conductive track pattern made from a metal alloy onto an electrically insulating surface.

### 2. Discussion of Background Information

The production of electric heating elements by thermal spray is a widely industrialized technology used in household goods and electric cars. The requirements with respect to power density and total power are increasing especially in battery electric vehicles due to the increasing size and mass of the battery packs. Therefore, the power density of the heaters and the number of tracks increase to increase the total heating power and better control the heat generation and its transfer to the transfer liquid. All this leads to lower tolerances in electrical resistance and therefore in the dimensions of the heating tracks which is impaired by the limited control of the coating thickness of the metallic layer out of which the heating circuits/tracks are formed.

Currently the design of the heating tracks is done by assuming a tight tolerance on the coating thickness of the electrically conductive heater layer which is usually a Ni 20Cr alloy of 25 to 50 μm. With moderate requirements to the total outlet power and size of the components it is possible to meet the tolerances of the resulting electric resistance which is determined by the specific resistivity of the material (which is assumed to be constant), the length of the track and the coating thickness. With increasing requirements leading to higher electrical resistance needed even small deviations in the range of 1 μm is leading to changes in the electrical resistance and the component cannot be used.

### SUMMARY

Embodiments are directed to a process in which electrical resistance of a heating track, which has been deposited by thermal spraying a conductive material, e.g., Ni 20Cr alloy, Ni 5Al, FeCrAl-alloys or TiO₂-based ceramic alloys, onto an insulating surface, e.g., Al₂O₃, Al₂O₃/Cr₂O₃ blends, Al₂O₃ 3TiO₂, Al₂O₃/ZrO₂ blends, YAG, ZrO₂-based ceramics, glass, or onto an optional bond coating on the substrate surface, is adjusted by post-processing. This post-processing adjustment can include, e.g., removing conductive material from an adjustment section of the deposited heating track. The adjustment section may be a specially designed section of the heating track for post-processing adjustment to remove conductive material from at least a portion of adjustment section to raise the electrical resistance of the heating track or the adjustment section may encompass the entire length of the heating track. In this way, tolerances of the electrical resistance of the heating track can be narrowed during the post-processing adjustment without generating more rejected parts. State of the art is that the electrical resistance may vary by +/−10% and is still not met for every part. With the post-correction-treatment the target is to make every part within specification and narrow down the tolerances to some+/−2%.

In embodiments, an adjustment or correction section of a heating track, e.g., in a long straight line part of a single heating track, can be provided that is 0.5 to 1.0 mm wider than a remaining portion of the heating track. After formation of the deposited heating track, and before post-processing adjustment, the electrical resistance single heating track is measured to determine whether the resistance is within the limits of a targeted range, typically +/−10%. The lower limit of electrical resistance is targeted because the post-adjustment can only remove material, which thereby increases the electrical resistance. Thus, if a target range is, e.g., 45-55 ohm (ideal value being 50 ohm) the initial layout is made to deliver 45 ohm. If the electrical resistance is found to be within the limits of the targeted range, no post-processing of the heating track is needed. However, in the event the electrical resistance is found to be too low, i.e., outside of the limits of the tolerance range for this heating track, post-processing adjustment is performed by removing material from the adjustment section, e.g., via laser ablation, ion sputtering, e-beam sputtering or micro milling, in an amount so that the electrical resistance falls within the limits of the tolerance range. Thus, while targeting the lower limit in the initial formation may result in more parts requiring post-correction, nearly all parts will be at the ideal value or within an effective range of the ideal value without scrap parts.

As a length of the adjustment section from which material is to be removed in post-processing adjustment will have a slightly lower resistance than the remainder of the heating track, the length of the removed material is preferably at least about 10% of the length of the single heating track so that the additional heat generated in the adjustment section can be more evenly distributed over the adjustment section. Otherwise, if the adjustment section is too short in length, there is a risk of insufficient heating occurring in the adjustment section.

The layout of the heating track includes an adjustment section of the track, which can be very simple in shape, e.g., an edge of a full length of a straight heating track, a straight heating track part of a meandering patterned heating track, or an increased width portion in the heating track. In producing the heating track, the dimensions are set in order to target an electrical resistance at a lower end of a targeted electrical resistance range. After producing the heating track, the value of the electrical resistance is measured. If the electrical resistance value is within the predetermined limits, no further action is required. In case the electrical resistance is lower than the predetermined minimum level, a width of the adjustment section is reduced in an amount to bring the electrical resistance into the target range.

As an alternative to adjust the width of the adjustment section it is also possible to reduce the coating thickness of the entire track, e.g. by grinding it.

Other exemplary embodiments and advantages of the present invention may be ascertained by reviewing the present disclosure and the accompanying drawing.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 illustrates a heating element formed from a coating system on a substrate;

FIG. 2 plots electrical resistance of the heater layer vs. number of parts in preparing components according to the known art without planned post processing;

FIG. 3 compares plots of electrical resistance of the heater layer vs. number of parts in preparing components according to the known art without planned post processing and according to embodiments in which post processing is planned;

FIG. 4, compares plots of electrical resistance of the heater layer vs. number of parts in preparing components according to the known art without planned post processing and according to embodiments in which post processing has been performed;

FIGS. 5-7 illustrate exemplary adjustment sections in heating tracks prior to post-processing adjustment in accordance with embodiments;

FIG. 8A illustrates a meandering patterned heating element as designed;

FIG. 8B illustrates the meandering patterned heating element of FIG. 8A with an adjusted track having thinner corners; and

FIG. 9 illustrates an exemplary flow diagram of the process according to the embodiments.

### DETAILED DESCRIPTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

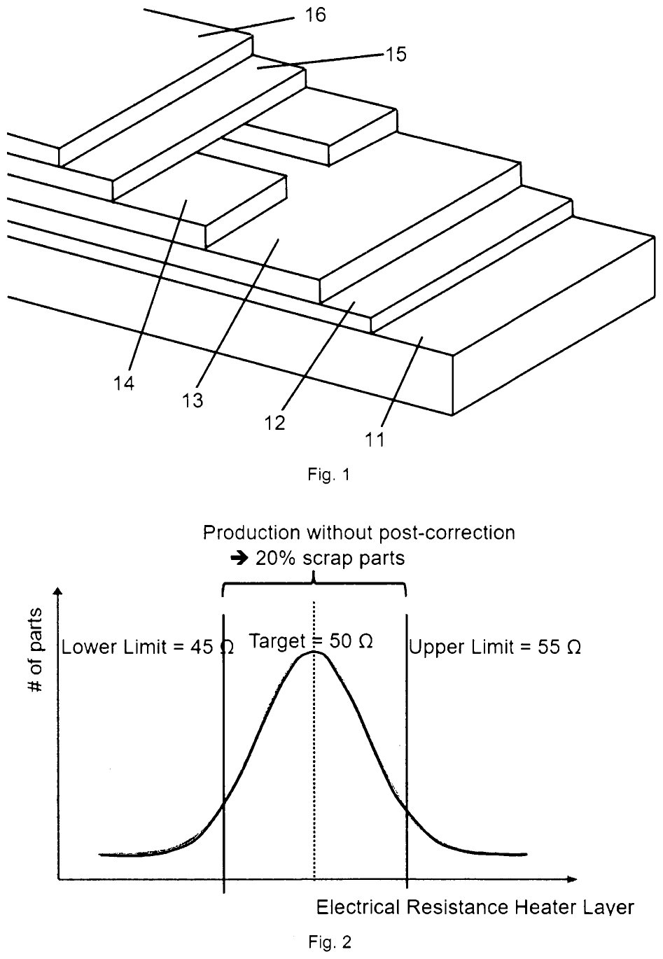

FIG. 1 illustrates an electric heating element 1, in which a coating system is formed on a substrate 11. The coating system is formed by an optional metallic bond coat 12, e.g., Ni 20Cr, Ni 5Al, Ni, Al, AlSi-alloys and FeCr- and FeCrNi-steels, to improve adhesion of the heating component to a substrate 11 that is preferably made from, e.g., low alloyed steel, stainless steel, aluminum and aluminum based alloys. A first insulating layer 13 comprised of an electrically insulating ceramic material, e.g., Al₂O₃, Al₂O₃/Cr₂O₃ blends, Al₂O₃ 3TiO₂, Al₂O₃/ZrO₂ blends, YAG, ZrO₂-based ceramics, glass, to electrically separate conductive heating track 14 from substrate 11/bond layer 12. Conductive heating track 14, which is formed by, e.g., via thermal spray processes, such as atmospheric plasma spray, combustion powder spray, combustion wire spray, electric arc wire spray, high velocity oxygen fuel spray and cold spray, comprises an electrically conductive material layer, e.g., Ni 20Cr, NiCr, pure Ni, Ni 5Al, FeCrAl-alloys or TiO₂-based ceramic alloys, that is, in particular, a patterned electrically conductive layer that is preferably applied with a meander type layout.

A second insulating layer 15 comprised of an electrically insulating ceramic material, e.g., Al₂O₃, Al₂O₃/Cr₂O₃ blends, Al₂O₃ 3TiO₂, Al₂O₃/ZrO₂ blends, YAG, ZrO₂-based ceramics, glass, is thermally sprayed onto and between conductive heating tracks 14, to electrically separate conductive heating track 14 from substrate 11/bond layer 12. Electrically conductive layer 16, e.g., copper or a copper based alloy, is patterned at zones via, atmospheric plasma spray, combustion powder spray, combustion wire spray, electric arc wire spray, high velocity oxygen fuel spray and cold spray, to allow conductive heating tracks 14 to be connected to an external power source (not shown), e.g., by soldering.

The width, length and thickness of the conductive heating tracks 14 are designed to produce a specific, predefined/predetermined electric resistance suitable to achieve a required total electric power output, e.g., total power between 2 to 6 kW per heater track at 400 to 800 V requiring a total resistance between 26 to 320Ω, preferably 3-4 kW at 400 V resulting in 40 to 53Ω. While the width and length of heating tracks 14 applied via thermal spray processes can be accurately controlled via, e.g., masking or post processing a coated layer, variations in the thickness of heating track 14, even small deviations, from the specific, predetermined production parameters will change the electrical resistance of heating track 14 from its intended electrical resistance value.

By way of non-limiting example, if a target electrical resistance for a heating track made of a material having a specific resistivity of 0.002 Ωmm is 30Ω+/−3Ω (+/−10%), and an intended coating thickness for the heating track is 0.30 mm and an intended width for the heating track is 2.9 mm, the length of the heating track will need to be 1300 mm, in spec, the heater track would have a resistance of 29.9Ω. In the event the coating thickness of the heating track material applied by thermal spraying is too high, i.e., exceeds the thickness used in calculating the dimensions for achieving the target electrical resistance, the electrical resistance of the resulting heating track may be below the targeted value. In this example if the coating thickness is less than 0.027 mm the part is above the upper limit of 33.2Ω, while 0.033 mm coating thickness would lead to a total resistance below the lower limit of 27.2Ω.

In a first example, a layout of heating tracks 14 in a heater element, which can be straight tracks or in a meandering pattern with straight or curved sections is described. Heating tracks 14, which can be applied by thermal spraying a conductive material, are produced with specific and predefined dimensions to achieve a target electrical resistance within the intended tolerance range. After heating tracks 14 are produced, the electrical resistance of the completed heating tracks 14 is measured, e.g., with a standard commercial multimeter, which is similar to the quality management for resistors, coils, etc. If the measured electrical resistance value is within the tolerance limits of 27 to 33Ω for the heater track, no further action is required and the heater element is accepted. However, in the event that the measured electrical resistance of the heating track is lower than, i.e., not within the tolerance limits of, the target minimum value, a width of the adjustment or correction section is reduced by removing material from the adjustment section in an amount to bring the electrical resistance into the target range, e.g., via laser ablation, ion sputtering, e-beam sputtering or micro milling. In this way, the electrical resistance of the heating track can be sufficiently raised to fall within the limits of the tolerance range. For example, when the full track is to be reduced in width, it is a linear relationship, e.g., if the track is measured to be 26Ω and it is desired to increase the resistance by 4Ω, the track width should be decreased by 4/26=15%.

FIG. 2 shows a plot of electrical resistance of the heater layer vs. number of parts in preparing components according to the known art and, therefore, without post correction. The plot shows a target resistance value of 50Ω and an acceptable range of +/−10%, i.e., between 45Ω and 55Ω. Due to variations in thermal spray technology, especially with respect to coating thickness, 20% of the parts are outside of the specified electrical resistance range and, therefore, become scrap parts.

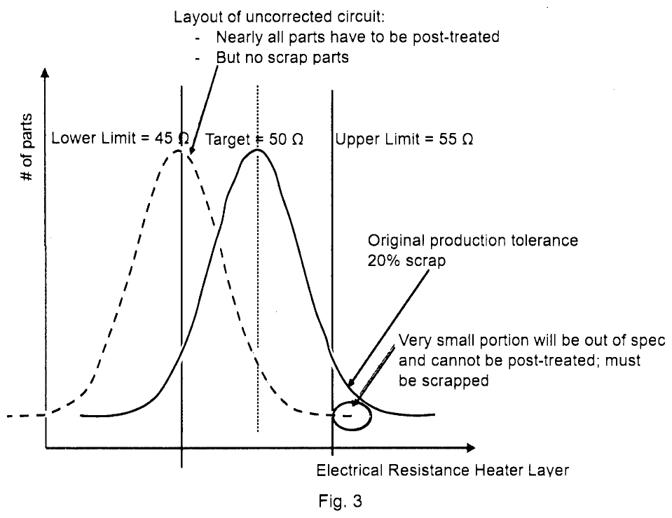

FIG. 3 shows a comparative plot of electrical resistance of the heater layer vs. number of parts in components prepared according to the known art/without post correction vs. components prepared according to the embodiments with planned post correction. This figure shows the plot for the known process centered on the target resistance value of 50Ω, while the plot for the embodiments (before post processing) is centered on the lower limit of the acceptable range, i.e., at 45Ω. As shown in FIG. 3, the tail of the plot for the known process extending beyond the upper limit of 55Ω represents 20% scrap, while the tail of the plot for the embodiments extending beyond the upper limit of 55Ω represents a very small portion <<20% that will be out of spec and cannot be post treated and, therefore, scrapped. Thus, according to embodiments, FIG. 3 shows the layout of the heater track is designed so that the center of the distribution is at the lower end of the tolerance range. In this way, while more parts may need correction, because the correction can only increase resistance of the heater track, only a very small portion of the tail above the upper limit is lost to scrap.

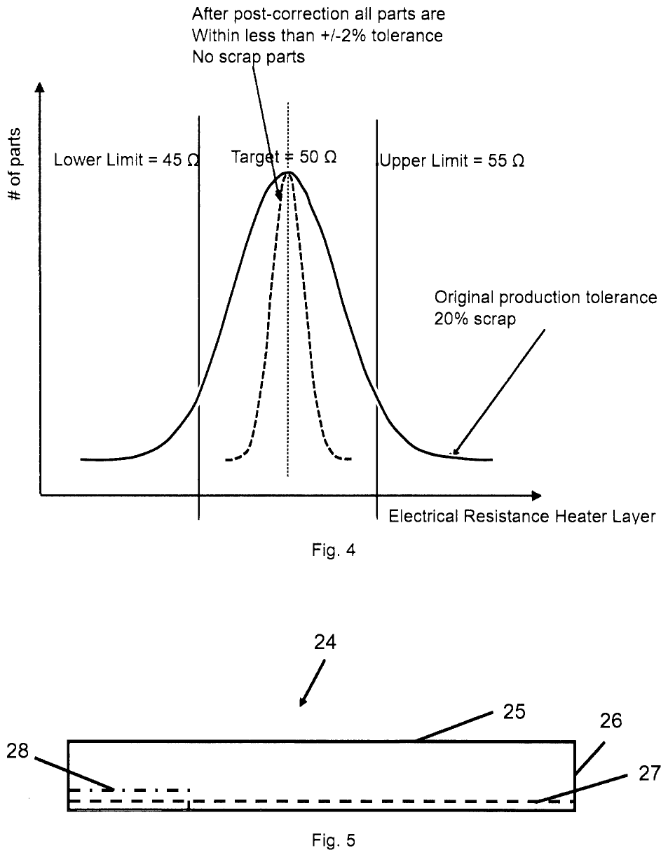

FIG. 4 shows a comparative plot of electrical resistance of the heater layer vs. number of parts in components prepared according to the known art/without post correction vs. components prepared according to the embodiments with post correction. This figure shows the plot for the known process centered on the target resistance value of 50Ω and the plot for the embodiments (after post processing) also centered on target resistance value 50Ω. As shown in FIG. 4, after post processing or post correction, all parts are within less than +/−2% tolerance, such that there are no scrap parts. Thus, FIG. 4 shows that, after post processing, nearly all parts will be in a much tighter tolerance, thereby avoiding scrap.

FIGS. 5-7 illustrate exemplary adjustment sections in heating tracks prior to post-processing adjustment in accordance with embodiments.

FIG. 5 shows a top view of an exemplary straight length of a heating track 24, showing its length 25 and width 26. The heating track dimensions of length 25 and width 26, as well as the thickness (not shown), are determined prior to thermally spraying the conductive material onto the substrate or the optional metallic bond coating to produce heating track 24 with an electrical resistance value that is within tolerance limits for the target electrical resistance. Preferably, the target electrical resistance for which length 25, width 26 and the thickness for thermally sprayed heating track 24 made from a material having a known specific resistivity is set to be at the lower end of the acceptable range for the electrical resistance. In the event the measured electrical resistance of heating track 24 is below the lower limit of the acceptable range, i.e., outside of the accepted range, conductive material can be removed from an edge of heating track 24 either along an entire length of heating track 24, e.g., along dashed line 27, or removed from an edge of at least a section of heating track 24, e.g., along dot-dashed line 28, to raise the electrical resistance of heating track 24 to a value within the acceptable range. The material can be removed preferably by laser ablation. Alternative methods are plasma etching and mechanical machining.

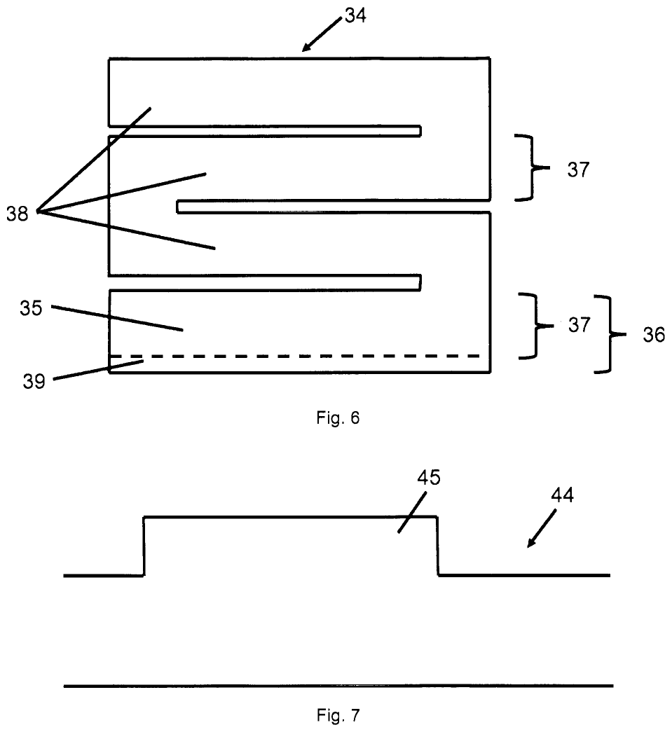

FIG. 6 shows a top view of a variation of FIG. 5, in which an exemplary heating track 34 is patterned in a meandering manner. As with the embodiment shown in FIG. 5, the length and width, as well as the thickness (not shown), of the meandering patterned heating track 34, is determined prior to thermally spraying the conductive material onto the substrate or the optional metallic bond coating to produce heating track 34 having an electrical resistance value that is within tolerance limits for the target electrical resistance. Preferably, one of the legs 35 of the meandering patterned heating track 34 is formed during the thermal spraying process to have a width 36 that is intentionally formed to be greater than the widths 37 of the remaining legs 38 of the meandering patterned heating track 34. This greater width portion of leg 35, i.e., adjustment section 39, is formed so that width 36 is, e.g., 20% wider than width 37. In this way, if the measured electrical resistance of heating track 34 is below the accepted variance for the target electrical resistance, material can be removed from the adjustment section 39, e.g., along an edge of an entire length of adjustment section 39 or along an edge of at least a part of the length of adjustment section 39, according to embodiments in order to increase the electrical resistance to fall within the accepted variance for the target electrical resistance for heating track 34.

By way of non-limiting example discussed above, if a target electrical resistance for a heating track made of a material having a specific resistivity of 0.002 Ωmm is 100Ω, i.e., within an accepted variation of +/−10%, and an intended coating thickness for the heating track is 0.01 mm and an intended width for the heating track is 5 mm, the length of the heating track will need to be 2500 mm. However, if the thickness of the heating track is even only 5% too high above the target thickness, which corresponds to 0.5 μm, the electrical resistance of the heating track decreases proportionally by 5% to 95Ω.

In this event, the heating track can be divided into two longitudinal sections, e.g., one section being 2000 mm long and another section being 500 mm long, see, e.g., FIG. 5 (dot-dashed line 28). The 500 mm long section is designed to be well accessible and/or made from a simple geometry, e.g., there can be a long straight track at the edge of the heater. This part can be easier altered than a meander. Thus, the target thickness for the heating track is 0.01 mm, which would result in a track resistance of 80Ω for the 2000 mm section and 20Ω for the 500 mm section or 100Ω for the heater track. In the event the thickness for the heating track is out of spec by 5%, i.e., the thickness of the coating for the heating track is 0.0105 mm, by reducing the width of the 500 mm section in a post-processing step section from 5 mm to 4 mm, while maintaining the width of the 2000 mm section, the deviation from the target electrical resistance in the heating track can be raised so that the unit is back on the target electric resistance value of 100Ω, i.e., with a track resistance of 76.2Ω for the 2000 mm section and 23.8Ω for the 500 mm section or 100Ω for the heater track. As discussed above, this post-processing can be done by laser ablation, ion sputtering, e-beam sputtering or micro milling. Moreover, because laser ablation is a preferred process for producing the heating track and/or heating track pattern for the track pattern out of the metallic thermal spray coating, it may also be preferable to use this same process for post-treatment to adjust the electrical resistance of the heating track.

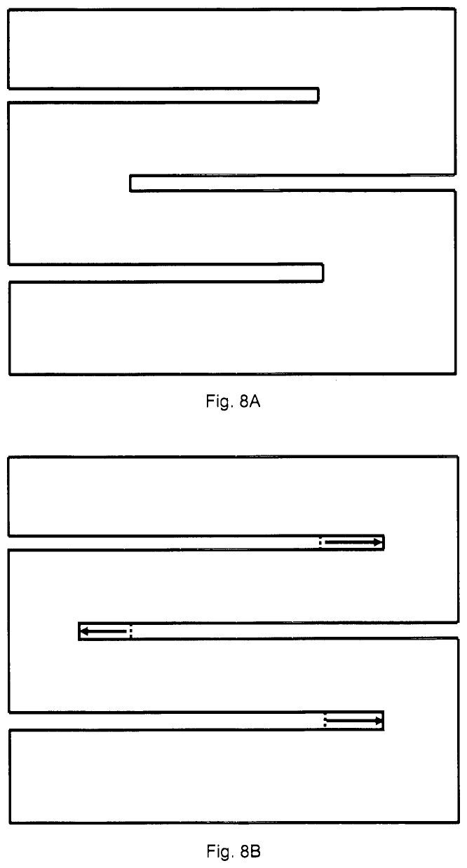

In another non-limiting example, the adjustment section of the heating track can be formed with a wider section, as shown, e.g., in FIG. 7. As discussed above, the wider adjustment section provided in the heating track is intended to provide the material needed for removal in order to adjust the electrical resistance of the heating track into the accepted variance for the intended electrical resistance. This adjustment section in the heater track can be, e.g., 10% wider than the remaining section of the heater track, which is not intended to be post-processed. Moreover, the length of the adjustment section is preferably at least 10% of the length of the heating track. With this design, the risk of local overheating in the heating track due to the track width being post-processed to a width less than a lower limit is reduced.

In still another non-limiting example, the heating track(s) of the heating element can be formed from or out of an electrically conductive coating. If, after the heating tracks are formed from the electrically conductive coating, the electrical resistance of the heating tracks is outside the tolerances for the target electrical resistance, the adjustment of the width of the track can be done over the full length, as shown, e.g., in FIG. 5 (dashed line 27). Assuming, e.g., a target electrical resistance for a heating track made of a material having a specific resistivity of 2×10⁻⁶ Ωm is 30Ω+/−10%, and an intended coating thickness for the heating track is 30 μm and an intended width for the heating track is 3 mm, the length of the heating track will need to be 1350 mm. However, if the thickness of the heating track is even only 2 μm too high above the target thickness, the electrical resistance of the heating track decreases to 28.1Ω. In this event, if the width of the heating track is reduced over the full length to 2.81 mm, e.g., by removing a 0.19 mm edge from the entire length of the heating track, the electrical resistance value of the heating track is increased into the acceptable variance range for the target electrical resistance value, e.g., 31Ω, which avoids the wasteful need to scrap the heating element. Again, this post-processing can be done by laser ablation, ion sputtering, e-beam sputtering or micro milling. Since laser ablation is the choice of method to produce the track pattern out of the metallic thermal spray coating it is also the recommended method for this post-treatment to adjust the electrical resistance. Moreover, software can be programmed to produce the additional removal of coating material, e.g., according to the following formula to calculate electrical resistance:

$$R = σ \frac{TrackLength}{TrackWidht * TrackThickness} .$$

The reduction of track width should nevertheless be limited to an amount 20% reduction in width that does not lead to hot spots due to the inhomogeneous structure of a thermal spray metallic coating, which results from the coating being made of splats that are 20-100 μm in diameter and 2-10 μm in thickness, as well as voids, oxides and other defects. Moreover, the resolution of laser for removing material is about 0.1 μm in track width.

In still another non-limiting exemplary embodiment, the meandering pattern for the heating track produced, e.g., by laser ablation, out of the conductive metal coating, can be formed with wider connections between two adjacent legs. As shown in FIG. 8A, the heating track can be formed with a track length chosen to generate an intended electrical resistance in the heating track that is at the lower end of the accepted tolerance. In the event the heating track formed in FIG. 8A has an electrical resistance that is outside the accepted variance from the target electrical resistance, a second laser ablation treatment can be performed on the heating track in FIG. 8A to reduce the width of the connectors is reduced, as shown in FIG. 8B. In this manner, the total length of the resistor track is increased, while the width of the connectors is decreased. As a result of this post-processing adjustment, the electrical resistance of the heating track will be increased in an effort to avoid the electrical resistance of the metal heater track and therefore avoids the wasteful need to scrap the heating element.

In still another non-limiting exemplary embodiment, the post-processing in order to increase the electrical resistance of the heater layer to the target electrical resistance, can be done by reducing the coating thickness of the heating track, e.g. by grinding.

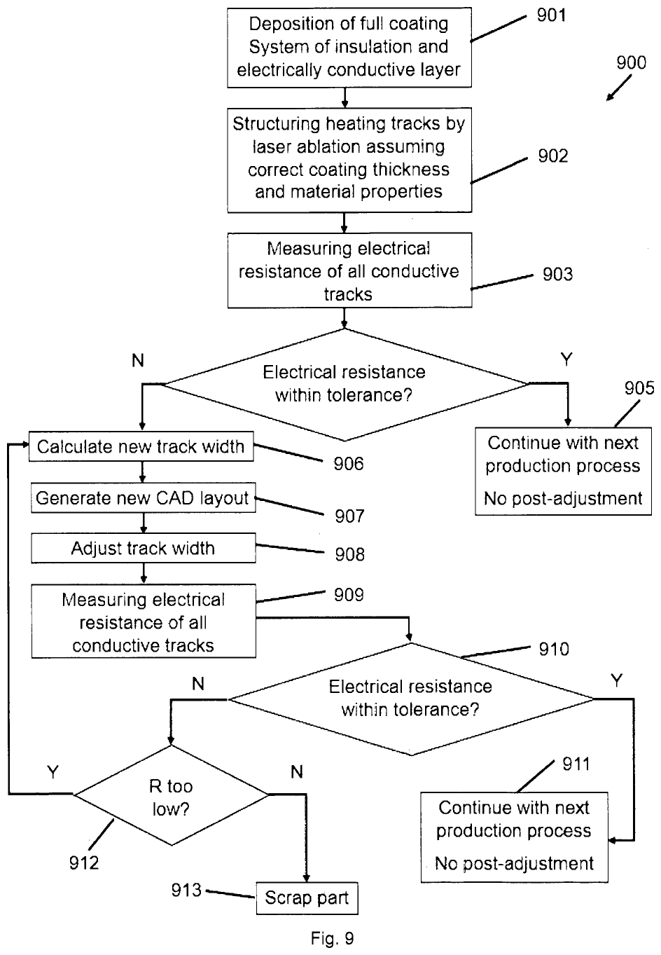

FIG. 9 shows an exemplary flow diagram 900 for a non-limiting example for producing a heating element. A blank for the heating element can be formed by deposition of a full coating system of insulation and an electrically conductive layer at 901, and the electrically conductive layer can be structured or formed into one or more heating tracks, e.g., via laser ablation, at 902. Via the laser ablation process, the length and width of the heating track(s) to be formed are based on a predetermined thickness and the material properties of the conductive material to achieve a target electrical resistance in the track(s). Alternatively, a mask can be applied to the substrate, optional bond layer and insulation so that one or more heating tracks are thermally sprayed onto the insulation layer with the determined length and width to achieve a target electrical resistance in the track(s), based on the predetermined thickness and the material properties of the conductive material.

Once the one or more heating tracks are formed, the electrical resistance of the formed heating tracks is measured at 903 and a determination is made at 904 whether the measured electrical resistance is within tolerances. If the electrical resistance of the heating tracks is within tolerances, the process accepts the heating element and continues with the production of the next element at 905. However, if the electrical resistance of the heating tracks is not within tolerances, the process at 906 calculates a new track width and generates a new CAD layout at 907.

According to this new CAD layout, the width of the heating track(s) out of tolerance is adjusted at 908, and the electrical resistance of the adjusted heating tracks (or all of the heating tracks) is measured at 909 and a determination is made at 910 whether the measured electrical resistance is within tolerances. If the electrical resistance of the heating tracks is within tolerances, the process accepts the heating element and continues with the production of the next element at 911. However, if the electrical resistance of the heating tracks is not within tolerances, the process determines at 912 whether the electrical resistance of the heater tracks is too low. If the electrical resistance is not too low, the heater element is scraped at 913. If the electrical resistance is determined to be too low at 912, the process returns to 906 to calculate a new track width and continue with the process.

It is noted that the foregoing examples have been provided merely for the purpose of explanation and are in no way to be construed as limiting of the present invention. While the present invention has been described with reference to an exemplary embodiment, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims.

1.-12. (canceled)

13. A process of forming an electric circuit, the process comprising:
providing a substrate;
thermally spraying a conductive material onto the substrate to form at least one conductive track;
measuring an electrical resistance of the at least one conductive track to determine whether the electrical resistance is within a set tolerance range; and
when the measured electrical resistance is outside the set tolerance range, removing a portion of the conductive material of the at least one conductive track in an amount sufficient to bring the measured electrical resistance within the set tolerance range.

14. The process of claim 13, wherein the electric circuit is a heating element and the at least one conductive track comprises at least one heating track.

15. The process of claim 14, wherein the at least one heating track is configured in a straight pattern or in a meandering pattern.

16. The process of claim 13, wherein removing the portion of the conductive material comprises removing material along at least one edge of the at least one conductive track.

17. The process of claim 16, wherein removing the portion of the conductive material comprises reducing a width of at least a portion of a length of the at least one conductive track.

18. The process of claim 17, wherein the portion of conductive material is removed from an entire length of the at least one conductive track.

19. The process of claim 13, wherein the conductive material is removed using laser ablation.

20. The process of claim 13, further comprising:
forming the at least one conductive track to have a set length, width, and thickness, the forming comprising:
(i) thermally spraying the conductive material to create a conductive layer on the substrate; and
(ii) removing portions of the conductive layer to define the at least one conductive track,
wherein the set length, width, and thickness of the at least one conductive track are selected, based on the material properties of the conductive material, to achieve a target electrical resistance.

21. The process of claim 13, further comprising:
applying a mask to the substrate so as to define a set length and width of the at least one conductive track; and
thermally spraying the conductive material onto the masked substrate to achieve a set thickness,
wherein, upon removal of the mask, the at least one conductive track has the set length, width, and thickness corresponding to a target electrical resistance.

22. The process of claim 13, wherein the at least one conductive track comprises an adjustment section having a width that is greater than a width of a remainder of the at least one conductive track.

23. The process of claim 22, wherein removing a portion of the conductive material from the adjustment section is effective to increase the electrical resistance of the at least one conductive track to within the set tolerance range.

24. The process of claim 13, further comprising measuring the electrical resistance of the at least one conductive track after removing the portion of conductive material, and if the electrical resistance is still outside the set tolerance range, removing an additional portion of the conductive material of the at least one conductive track.
